(19) United States
(12) Patent Application Publication
(10) Pub. No.: US 2021/0336147 A1
(43) Pub. Date: Oct. 28, 2021

(54) MASK

(71) Applicant: Wuhan China Star Optoelectronics Semiconductor Display Technology Go., Ltd., Wuhan (CN)

(72) Inventor: Jian YE, Wuhan (CN)

(21) Appl. No.: 16/488,589

(22) PCT Filed: Jan. 2, 2019
(86) PCT No.: PCT/CN2019/070150

§ 371 Date: Aug. 25, 2019

(30) Foreign Application Priority Data
Dec. 4, 2018 (CN) 201811474273.4

(51) Int. Cl. H01L 51/00; C23C 14/04; H01L 51/56

(52) U.S. Cl. CPC H01L 51/0011; H01L 51/56; H01L 51/001; C23C 14/042

(57) ABSTRACT

The present invention provides a mask comprising: a frame; a shielding body, the shielding body comprising a plurality of first shielding strips and a plurality of second shielding strips; the first shielding strips and the second shielding strips are intersected to form a plurality of open areas in an array arrangement; the mask substrate comprising a plurality of mask units comprising a vapor deposition region corresponding to a row or a column of the open areas, and a position of each of the open areas corresponding to a position of a display region of a display panel.

### CROSS REFERENCE TO RELATED APPLICATION

This application claims the priority of International Application No. PCT/CN2019/070150, filed on Jan. 2, 2019, which claims priority to Chinese Application No. 201811474273.4, filed on Dec. 4, 2018. The entire disclosures of each of the above applications are incorporated herein by reference.

### BACKGROUND OF INVENTION

### Field of Invention

The present invention relates to the field of display technologies, and in particular, to a mask.

### Description of Prior Art

The demand for full screens is becoming more and more urgent, that is, the screen occupation ratio of an entire electronic device is required to be higher and higher. Taking a smartphone as an example, the aspect ratio of the mobile phone screen has increased from the existing 16:9 to the current mainstream 18:9, 18.5:9, 19.5:9, and 20:9.

At present, mobile phone screens mostly use organic light emitting diode (OLED) displays. OLEDs are generally manufactured by vacuum deposition, where organic light emitting material is heated in a crucible, changes from solid to gaseous, and then is deposited in sub-pixel regions of an array substrate through openings of a fine metal mask (FMM), that is, the regions defined by a pixel defining layer (PDL). The FMM is provided with openings corresponding to the R/G/B sub-pixels one to one. When depositing a certain color of the organic light emitting material, an FMM of a corresponding color is used.

However, at present, the main manufacturing method of FMM is wet etching. First, a pattern of openings with specific sizes, that is, a photomask, is formed, and then an FFM is formed by manufacturing corresponding openings on a metal thin film by etching corresponding openings by a yellow etching process, that is, corresponding openings are made in sub-pixel regions. The production cost of the pattern is usually expensive and the cost is high. Therefore, it is expensive to manufacture an FFM, thereby increasing the production cost. When the panel size changes, the FMM needs to be remade to make the openings corresponding to the new display area, which is inflexible.

Therefore, it is necessary to provide a mask to solve the problems of prior art.

### SUMMARY OF INVENTION

The object of the present invention is to provide a mask which can reduce production costs and increase flexibility.

In order to solve the above technical problem, the present invention provides a mask comprising:

a frame;

a shielding body comprising a plurality of first shielding strips arranged along a first direction and a plurality of second shielding strips arranged along a second direction, wherein the first shielding strips and the second shielding strips are disposed to intersect each other, wherein ends of the first shielding strips and ends of the second shielding strips are fixed on the frame, wherein the first shielding strips and the second shielding strips are intersected to form a plurality of open areas in an array arrangement; and

a mask substrate comprising a plurality of mask units, both ends of the mask units fixed on the frame, the mask units disposed on the shielding body and comprising a vapor deposition region corresponding to a row or a column of the open areas, a position of each of the open areas corresponding to a position of a display region of a display panel, the vapor deposition region comprising a plurality of sub-vapor deposition regions corresponding to the positions of the open areas, the mask unit further comprising two buffer regions, positioned on one side of two sides of the vapor deposition region.

In the mask of the present invention, any two adjacent sub-vapor deposition regions are spaced disposed.

In the mask of the present invention, a spacing between any two adjacent sub-vapor deposition regions is same.

In the mask of the present invention, an area of each of the sub-vapor deposition regions is greater than an area of a corresponding open area.

In the mask of the present invention, each of the sub-vapor deposition regions comprises an effective vapor deposition region and a virtual vapor deposition region, the virtual vapor deposition region is disposed outside the effective vapor deposition region, the effective vapor deposition regions correspond to the positions of the open areas, at least the effective vapor deposition regions and the virtual vapor deposition regions are provided with a plurality of first holes.

In the mask of the present invention, a same mask unit corresponds to a plurality of display regions having different areas.

In the mask of the present invention, the buffer regions and the vapor deposition region are spaced disposed.

In the mask of the present invention, the buffer regions are provided with a plurality of second holes.

In the mask of the present invention, the first shielding strips and the second shielding strips are integrally formed.

In the mask of the present invention, each of the vapor deposition regions on each of the mask units has a same size.

The present invention provides a mask, comprising:

a frame;

a shielding body comprising a plurality of first shielding strips arranged along a first direction and a plurality of second shielding strips arranged along a second direction, wherein the first shielding strips and the second shielding strips are disposed to intersect each other, wherein ends of the first shielding strips and ends of the second shielding strips are fixed on the frame, wherein the first shielding strips and the second shielding strips are intersected to form a plurality of open areas in an array arrangement; and

a mask substrate comprising a plurality of mask units, both ends of the mask units fixed on the frame, the mask units disposed on the shielding body and comprising a vapor deposition region corresponding to a row or a column of the open areas, a position of each of the open areas corresponding to a position of a display region of a display panel.

In the mask of the present invention, the vapor deposition region comprising a plurality of sub-vapor deposition regions corresponding to the positions of the open areas.

In the mask of the present invention, any two adjacent sub-vapor deposition regions are spaced disposed.

In the mask of the present invention, a spacing between any two adjacent sub-vapor deposition regions is same.

In the mask of the present invention, an area of each of the sub-vapor deposition regions is greater than an area of a corresponding open area.

In the mask of the present invention, each of the sub-vapor deposition regions comprises an effective vapor deposition region and a virtual vapor deposition region, the virtual vapor deposition region is disposed outside the effective vapor deposition region, the effective vapor deposition regions correspond to the positions of the open areas, at least the effective vapor deposition regions and the virtual vapor deposition regions are provided with a plurality of first holes.

In the mask of the present invention, a same mask unit corresponds to a plurality of display regions having different areas.

In the mask of the present invention, the mask unit further comprising two buffer regions poisoned on one side of two sides of the vapor deposition region.

In the mask of the present invention, the buffer regions and the vapor deposition regions are spaced disposed.

In the mask of the present invention, the buffer regions are provided with a plurality of second holes.

The mask of the present invention is provided with a vapor deposition region corresponding to a row or a column of the open areas, a position of each of the open areas corresponding to a position of a display region of a display panel, thus, a plurality of different size panels can be fabricated through one mask, which reduces production costs and increases flexibility.

### BRIEF DESCRIPTION OF DRAWINGS

FIG. 1 is a structural diagram of a mask of the present invention;

FIG. 2 is a structural diagram of a mask unit of the present invention;

FIG. 3 is a structural diagram showing a first structure of the mask unit of the present invention;

FIG. 4 is a structural diagram showing a second structure of a mask unit of the present invention;

FIG. 5 is a structural diagram showing a third structure of the mask unit of the present invention;

FIG. 6 is a structural diagram showing a fourth structure of a mask unit of the present invention;

FIG. 7 is a structural diagram showing a fifth structure of a mask unit of the present invention;

FIG. 8 is a structural diagram showing a sixth structure of a mask unit of the present invention;

FIG. 9 is a top view of a mask unit and openings of the present invention;

FIG. 10 is a structural diagram of a display panel during vapor deposition of the present invention.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

Please refer to FIG. 1 to FIG. 10. FIG. 1 is a structural diagram of a mask of the present invention.

As shown in FIG. 1, the mask 100 of the present invention includes a shielding body 10, a mask substrate 20, and a frame 40, and further includes an alignment plate 30.

The shielding body 10 includes a plurality of first shielding strips 12 and a plurality of second shielding strips 13, and the plurality of the first shielding strips 12 and the plurality of the second shielding strips 13 are disposed in an intersected way.

The first shielding strips 12 are arranged in a first direction, and the second shielding strips 13 are arranged in a second direction, wherein the first direction is, for example, a horizontal direction, the second direction is a vertical direction, and the first direction is perpendicular to the second direction. Ends of the first shielding strips 12 and ends of the second shielding strips 13 are fixed on the frame 40; for example, ends of the first shielding strips 12 and ends of the second shielding strips 13 are all welded to the frame 40. The first shielding strips 12 and the second shielding strips 13 are intersected to form a plurality of open areas in an array arrangement. In an embodiment, the first shielding strips 12 and the second shielding strips 13 are integrally formed. The first shielding strips 12 are welded to the second shielding strips 13 when they are formed separately. The material of the first shielding strips 12 and the second shielding strips 13 can be stainless steel. The shielding body 10 is used to shield regions that do not need to be vapor deposited and to support the mask substrate 20. It can be understood that, FIG. 1 shows a schematic diagram in which regions do not need vapor deposition are shielded by the shielding body 10.

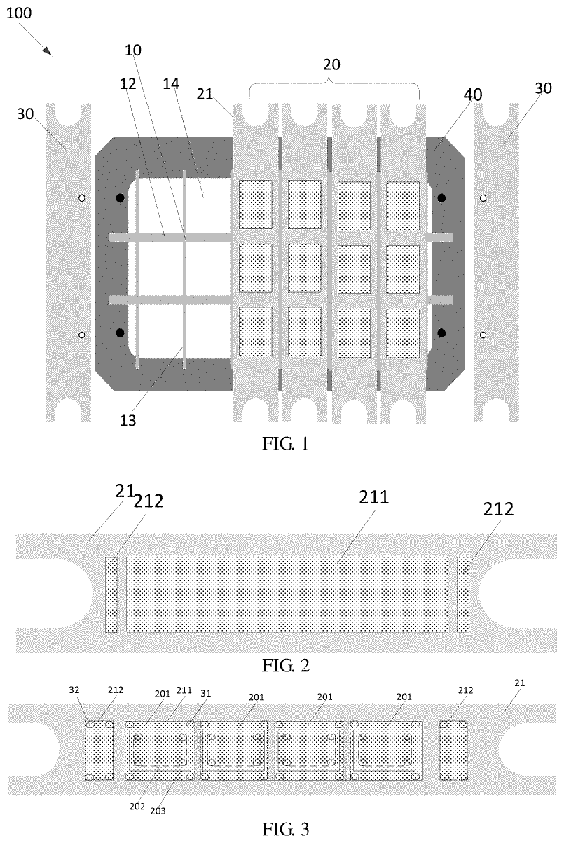

The mask substrate 20 includes four mask units 21, both ends of which are fixed to the frame 40, wherein the mask units 21 are welded to the frame 40. The mask unit 21 is disposed on the shielding body 10. The number of the mask units 21 corresponds to the number of columns of the display panel to be evaporated. For example, if four columns of display panels need to be deposited (each column includes a plurality of display panels), then four mask units 21 are required. It should be noted that the vapor deposition of different colors of organic light emitting materials in each display panel uses different mask substrates, for example, the vapor deposition of green organic light-emitting material uses a mask substrate, the vapor deposition of red organic light-emitting material uses a mask substrate, and the vapor deposition of blue organic light-emitting material uses a mask substrate. In a vapor deposition process, sub-pixel regions of a same color of a plurality of display panels are vapor-deposited by using a mask substrate to obtain an organic light emitting unit of a corresponding color. Although FIG. 2 only exemplifies a mask substrate 20 which includes four mask units 21, the present invention is not limited thereto. The mask substrate 20 can include two or more mask units 21. The material of the mask substrate 20 could be invar, which is designed by full etching.

As shown in FIG. 2, the mask unit 21 includes a vapor deposition region 211, the vapor deposition region 211 corresponds to a row or a column of open areas 14, and a position of each of the open areas 14 corresponding to a position of a display region of a display panel. Combined with FIG. 1, an open area 14 corresponds to a display area of a display panel, and the vapor deposition region 211 of the same mask unit 21 corresponds to one row or one column of display panels, so that the same mask substrate 20 corresponds to multiple display panels. Wherein, the display area includes a plurality of sub-pixel areas for forming an organic light emitting unit by vapor-depositing a corresponding color of the organic light emitting material.

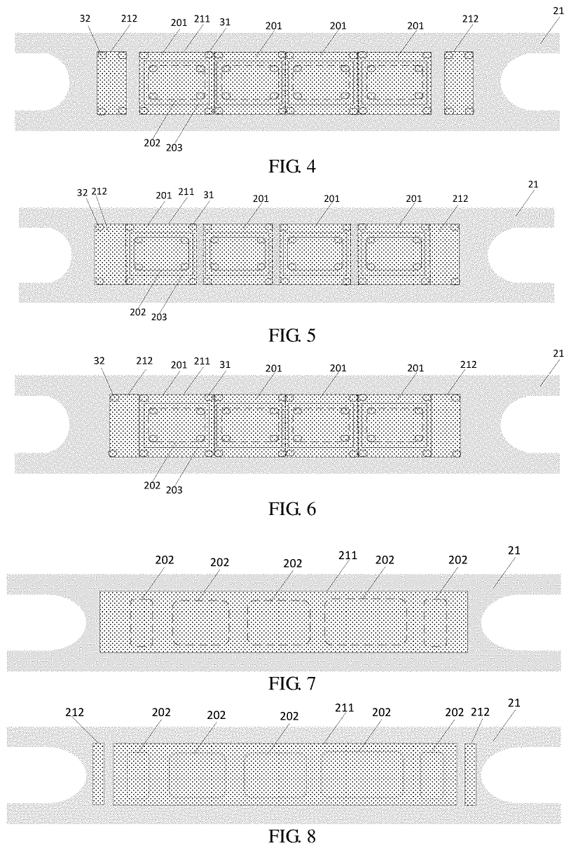

As shown in FIG. 3 or FIG. 4, the vapor deposition region 211 includes a plurality of sub-vapor deposition regions 201 corresponding to the positions of an open area 14 of a row or a column of the open areas. The sub-vapor deposition regions 201 correspond to the positions of the open areas of the corresponding columns or corresponding rows. For example, the vapor deposition region 211 corresponds to the positions of the open area of the third row, and one of the sub-vapor deposition regions 201 of the vapor deposition region 211 corresponds to the position of the open area 14 of the third row of open areas. The area of each of the sub-vapor deposition regions 201 is larger than the area of the open area 14. Therefore, the position of the vapor deposition region outside the display area is blocked by the shielding body 10, that is, the position not needing vapor deposition is blocked.

The sub-vapor deposition regions 201 include an effective vapor deposition region 202 and a virtual vapor deposition region 203. The virtual vapor deposition region 203 is located outside the effective vapor deposition region 202, and the sub-vapor deposition regions 201 are located outside the virtual vapor deposition region 203. The effective vapor deposition region 202 corresponds to the position of the open areas 14. In one embodiment, at least the effective vapor deposition region 202 and the virtual vapor deposition region 203 are provided with a plurality of first holes 31. In another embodiment, the entire vapor deposition region 211 is provided with the plurality of first holes 31. The first holes 31 are through holes. The area of the effective vapor deposition region 202 is greater than or equal to the area of the corresponding open area 14, so that the size (length and width) of the open area 14 can be adjusted within an area not greater than the area of the vapor deposition zone 211, so that it is easy to make display panels of different sizes, and to improve flexibility.

In one embodiment, as shown in FIG. 3, two adjacent sub-vapor deposition regions 201 are spaced disposed. Moreover, the spacing between the adjacent two sub-vapor deposition regions 201 is small, thereby increasing the strength of the mask unit 21 and avoiding wrinkles when the mask substrate is stretched. The spacing between adjacent two of the sub-vapor deposition regions 201 is equal to improve the uniformity of a vapor deposited film (i.e. the organic light emitting material).

In another embodiment, as shown in FIG. 4, two adjacent sub-vapor deposition regions 201 are disposed adjacently. That is, there is no gap between two adjacent sub-vapor deposition regions 201.

As shown in FIGS. 3 to 6, the mask unit 21 further includes two buffer regions 212, positioned on one side of two sides of the vapor deposition region 211. That is, one of the buffer regions 212 is located on one side of the vapor deposition region 211. The buffer regions disposed on both sides of the vapor deposition region can act as anti-deformation when the mask substrate 20 is stretched, and can avoid excessive offset of the position and size of the effective vapor deposition region 202. Therefore, the thickness of the film of the vapor deposition material is made uniformly to ensure that the position of the vapor deposition region 211 and position of the display area on an array substrate are corresponded, and to avoid offset.

The buffer regions 212 are provided with a plurality of second holes 32. The second holes 32 are through holes. It will be understood that the number and position of the first and second holes in the figures are merely illustrative and are not intended to limit the invention. More holes can be provided in the buffer regions 212 and the vapor deposition region 211. The number and position of the holes can also be set according to actual needs. It will be understood that the holes are not illustrated in the remaining figures.

In an embodiment, as shown in FIG. 3 or FIG. 4, the buffer regions 212 are spaced apart from the vapor deposition region 211.

In one embodiment, as shown in FIG. 5 or FIG. 6, the buffer regions 212 and the vapor deposition region 211 are disposed adjacent to each other. That is, the buffer regions 212 and the vapor deposition region 211 are not spaced apart.

In an embodiment, as shown in FIG. 7 or FIG. 8, the areas of the effective vapor deposition regions 202 in the vapor deposition region 211 are not equal. That is, a same mask unit 21 corresponds to opening areas 14 of different sizes, or a same mask unit 21 corresponds to display areas of different sizes. The areas of the plurality of open areas 14 or display areas in the same row or in the same column are not equal. In an embodiment, the areas of the at least two display areas are not equal. In another embodiment, the areas of each display area are not equal.

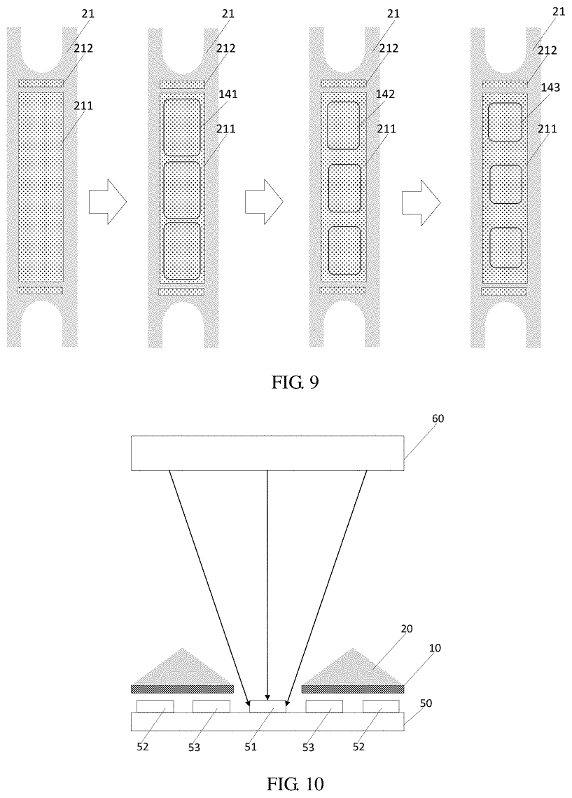

Referring to FIG. 9, the mask substrate 20 of the present invention can fabricate organic light emitting diode (OLED) panels of different sizes. The mask substrate 20 can be combined with open areas of different sizes, wherein 141 to 143 represent open areas of different sizes. Each of the vapor deposition regions 211 on each of the mask unit 21 has a same size. Therefore, when the size of the OLED panels does not change greatly, for example, the aspect ratio only changes from the original 16:9 to 18:9 or 20:9, and the sub-pixel area has a same size, the OLED panels can share a same mask substrate 20, and only need to match a corresponding shielding body. That is, the mask substrate 20 in the present invention can be used to fabricate a plurality of different sized panels, especially when the pixel size of the OLED panels remains unchanged and the panel size is fine-tuned, a same mask unit can be used to fabricate OLED panels with various sizes. It is possible to avoid designing a plurality of different film substrates separately for each panel, thereby saving the manufacturing cost.

Compared with using a plurality of different mask substrates 20 separately, using a same mask substrate 20 to produce display panels of different sizes can save the cost in the process of fabricating the mask substrate, and improve the utilization and flexibility of the mask substrate.

The method of fabricating an OLED panel by using the above mentioned mask comprises the following steps:

S101, providing a completed array substrate 50 and a mask.

Taking a single display panel as an example, as shown in FIG. 10, for example, the array substrate 50 includes a switch array layer and a pixel defining layer, and the array substrate has a sub-pixel region (to be vapor-deposited) in a one-to-one correspondence with the organic light emitting unit. The sub-pixel region includes a red sub-pixel region 51, a green sub-pixel region 52, and a blue sub-pixel region 53.

The mask substrate 20 includes three kinds of mask substrates of R/G/B, and the mask substrate of each color includes a plurality of mask units. Each of the color mask substrate can be used for manufacturing display panels of different sizes. FIG. 10 is only an example of a mask substrate.

S102, mounting the mask and the array substrate on a vapor deposition machine.

Taking a red organic light emitting unit as an example, a red organic light emitting material in an vapor deposition source 60 is deposited on the red sub-pixel region 51 on the array substrate 50 through the holes in the mask units 20 and the open regions on the shielding body 10.

That is, the mask units of the present invention are combined with the shielding bodies of different opening sizes to form a complete set of masks, and OLED panels of different sizes are produced by a vapor deposition process.

The mask of the present invention is provided with a vapor deposition region corresponding to a row or a column of the open areas, a position of each of the open areas corresponding to a position of a display region of a display panel, thus, a plurality of different sized panels can be fabricated through one mask, which reduces production costs and increases flexibility.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. A mask, comprising:
a frame;
a shielding body comprising a plurality of first shielding strips arranged along a first direction and a plurality of second shielding strips arranged along a second direction, wherein the first shielding strips and the second shielding strips are disposed to intersect each other, wherein ends of the first shielding strips and ends of the second shielding strips are fixed on the frame, wherein the first shielding strips and the second shielding strips are intersected to form a plurality of open areas in an array arrangement; and
a mask substrate comprising a plurality of mask units, both ends of the mask units fixed on the frame, the mask units disposed on the shielding body and comprising a vapor deposition region corresponding to a row or a column of the open areas, a position of each of the open areas corresponding to a position of a display region of a display panel, the vapor deposition region comprising a plurality of sub-vapor deposition regions corresponding to the positions of the open areas, the mask units further comprising two buffer regions, positioned on one side of two sides of the vapor deposition region.

2. The mask according to claim 1, wherein any two adjacent sub-vapor deposition regions are spaced disposed.

3. The mask according to claim 1, wherein a spacing between any two adjacent sub-vapor deposition regions is same.

4. The mask according to claim 1, wherein an area of each of the sub-vapor deposition regions is greater than an area of a corresponding open area.

5. The mask according to claim 1, wherein each of the sub-vapor deposition regions comprises an effective vapor deposition region and a virtual vapor deposition region, the virtual vapor deposition region is disposed outside the effective vapor deposition region, the effective vapor deposition regions correspond to the positions of the open areas, at least the effective vapor deposition regions and the virtual vapor deposition regions are provided with a plurality of first holes.

6. The mask according to claim 1, wherein a same mask unit corresponds to a plurality of display regions having different areas.

7. The mask according to claim 1, wherein the buffer regions and the vapor deposition region are spaced disposed.

8. The mask according to claim 1, wherein the buffer regions are provided with a plurality of second holes.

9. The mask according to claim 1, wherein the first shielding strips and the second shielding strips are integrally formed.

10. The mask according to claim 1, wherein each of the vapor deposition regions on each of the mask units has a same size.

11. A mask, comprising:
a frame;
a shielding body comprising a plurality of first shielding strips arranged along a first direction and a plurality of second shielding strips arranged along a second direction, wherein the first shielding strips and the second shielding strips are disposed to intersect each other, wherein ends of the first shielding strips and ends of the second shielding strips are fixed on the frame, wherein the first shielding strips and the second shielding strips are intersected to form a plurality of open areas in an array arrangement; and
a mask substrate comprising a plurality of mask units, both ends of the mask units fixed on the frame, the mask units disposed on the shielding body and comprising a vapor deposition region corresponding to a row or a column of the open areas, a position of each of the open areas corresponding to a position of a display region of a display panel.

12. The mask according to claim 11, wherein the vapor deposition region comprising a plurality of sub-vapor deposition regions corresponding to the positions of the open areas.

13. The mask according to claim 11, wherein any two adjacent sub-vapor deposition regions are spaced disposed.

14. The mask according to claim 11, wherein a spacing between any two adjacent sub-vapor deposition regions is same.

15. The mask according to claim 11, wherein an area of each of the sub-vapor deposition regions is greater than an area of a corresponding open area.

16. The mask according to claim 11, wherein each of the sub-vapor deposition regions comprises an effective vapor deposition region and a virtual vapor deposition region, the virtual vapor deposition region is disposed outside the effective vapor deposition region, the effective vapor deposition regions correspond to the positions of the open areas, at least the effective vapor deposition region and the virtual vapor deposition region are provided with a plurality of first holes.

17. The mask according to claim 11, wherein a same mask unit corresponds to a plurality of display regions having different areas.

18. The mask according to claim 11, wherein the mask unit further comprising two buffer regions poisoned on one side of two sides of the vapor deposition region.

19. The mask according to claim 18, wherein the buffer regions and the vapor deposition region are spaced disposed.

20. The mask according to claim 18, wherein the buffer regions are provided with a plurality of second holes.
